(19) United States
(12) Patent Application Publication
(10) Pub. No.: US 2020/0344911 A1
(43) Pub. Date: Oct. 29, 2020

(54) MIDDLE SLIDE LATCH

(71) Applicant: HEWLETT PACKARD ENTERPRISE DEVELOPMENT LP, Houston, TX (US)

(72) Inventors: Daniel W. Tower, Houston, TX (US); Kenny Pham, Houston, TX (US)

(21) Appl. No.: 16/393,690

(22) Filed: Apr. 24, 2019

(51) Int. Cl. H05K 7/18; A47B 88/49; A47B 88/443

(52) U.S. Cl. CPC H05K 7/183; A47B 88/443; A47B 88/49

(57) ABSTRACT

A rail kit, comprising: an outer slide; a middle slide retained by the outer slide, wherein the middle slide is horizontally slidable, relative to the outer slide, to a first position and a second position and wherein the middle slide includes a first latch to stop the middle slide from extending to the second position when the middle slide is extended from a fully inserted position to the first position; and an inner slide retained by the middle slide, wherein the inner slide is horizontally slidable, relative to the middle slide, to the first position and the second position and wherein the inner slide includes a second latch, wherein when the second latch is depressed and when the inner slide and middle slide are in the first position, the first latch is actuated and the inner slide and middle slide are extended to the second position.

### BACKGROUND

Computing devices, particularly servers, may be added to or installed in a rack. A rack may be a structure for housing multiple computing devices. Generally, a rack may consist of four posts or columns with mounting holes or apertures to facilitate the addition or mounting of computing devices. A rail kit may attach to a computing device and to a rack, thus allowing a computing device to be mounted to the rack. Further the rail kit may allow the computing device to be slid in and out of the rack while remaining mounted to the rack, thus providing access to a user for a portion of the computing device. The rail kit may include a latch to prevent slide rails from being completely removed from the rail kit.

### BRIEF DESCRIPTION OF THE DRAWINGS

Non-limiting examples of the present disclosure are described in the following description, read with reference to the figures attached hereto and do not limit the scope of the claims. In the figures, identical and similar structures, elements or parts thereof that appear in more than one figure are generally labeled with the same or similar references in the figures in which they appear. Dimensions of components and features illustrated in the figures are chosen primarily for convenience and clarity of presentation and are not necessarily to scale. Referring to the attached figures:

FIG. 1 is a block diagram of a rail kit, according to an example;

FIGS. 2A and 2B are schematic views of a middle slide, according to an example;

FIGS. 3A and 3B are schematic views of a rail kit in a retracted position, according to an example;

FIGS. 4A and 4B are schematic views of a rail kit in a partially extended position, according to an example;

FIG. 5 is a schematic view of the opposite side of a section of an outer slide and a latch, according to an example; and

FIGS. 6A and 6B are schematic views of a rail kit in an extended position, according to an example.

### DETAILED DESCRIPTION

In the following detailed description, reference is made to the accompanying drawings which form a part hereof, and in which is depicted by way of illustration specific examples in which the present disclosure may be practiced. It is to be understood that other examples may be utilized and structural or logical changes may be made without departing from the scope of the present disclosure.

Computing devices, particularly servers, may be added to or installed in a rack. A rack may be a structure for housing multiple computing devices. Generally, a rack may consist of four posts or columns with mounting holes to facilitate the addition or mounting of computing devices. A rail kit may attach to a computing device and to a rack, thus allowing a computing device to be mounted to the rack. Further the rail kit may allow the computing device to be slid in and out of the rack while remaining mounted to the rack, thus providing access to a user for a portion of the computing device. The rail kit may include a latch to prevent slide rails from being completely removed from the rail kit.

A rail kit may include one stopping point. In other words, the stopping point may be when the rail kit is fully extended. Further, for computing devices the single stopping point may cause issues. For example, some computing devices may be longer than other computing device. Further still, a user may want to access different devices in the computing device. However, in the case of the one stopping point, access to different areas, components, or devices of the computing device may be difficult or inconvenient.

Thus, the present disclosure describes examples of new rail kits that may include a middle latch which allows for a second stopping point. Examples may allow users to access various components at either stopping point.

Examples, described herein include a rail kit. The rail kit includes an outer slide, a middle slide, and an inner slide. The inner slide may be nested in, supported by, or retained by the middle slide. The middle slide may be nested in, supported by, or retained by the outer slide. The middle slide may include a latch. As the inner slide and middle slide are pulled, the inner slide and middle slide may stop at a first point/position or a partially extended position. The latch may prevent further movement of the inner slide and middle slide in any direction (other than, in some examples, “wiggle room”). To move the inner slide and middle slide further out or in from the first point/position or the partially extended position, a second latch located on the inner slide may be depressed, actuating the latch on the middle slide, thus allowing movement of the inner slide and middle slide to either an extended position or a retracted position. In another example, the latch may be actuated by pulling, with a greater than normal force, the inner slide, which may force the latch back to the latches original position, thus allowing for movement of the inner slide and middle slide to either an extended position or a retraced position.

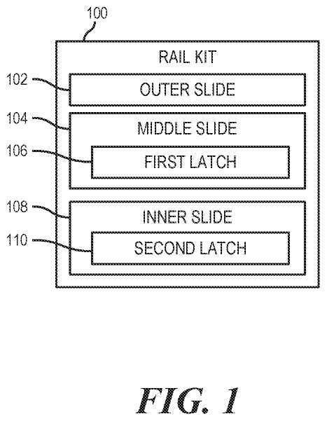

FIG. 1 is a block diagram of a rail kit 100, according to an example. The rail kit 100 may include an outer slide 102. The rail kit 100 may also include a middle slide 104. The outer slide 102 may retain the middle slide 104. The middle slide 104 may slide horizontally to a first position and a second position in relation to the outer slide (or back to a fully retracted position). The rail kit 100 may also include an inner slide 108. The middle slide 104 may retain the inner slide 108. The inner slide 108 may slide horizontally to the first position and the second position (or back to a fully retracted position) in relation to the middle slide 104. The middle slide 104 may include a first latch 106 to stop the middle slide 104 and inner slide 108 at the first position. In other words, the first latch 106 may prevent the middle slide 104 and inner slide 108 from sliding to either the second position or to a fully retracted position (or in other words, in any direction). The inner slide 108 may include a second latch 110. The second latch 110 may actuate the first latch 106, thus allowing the middle slide 104 and inner slide 108 to move from the first position to either the second position or the fully retracted position.

As used herein, a “computing device” may be a storage array, storage device, storage enclosure, server, blade server, desktop or laptop computer, computer cluster, node, partition, virtual machine, or any other device or equipment including a controller, a processing resource, or the like. In examples described herein, a “processing resource” may include, for example, one processor or multiple processors included in a single computing device or distributed across multiple computing devices. As used herein, a “processor” may be at least one of a central processing unit (CPU), a semiconductor-based microprocessor, a graphics processing unit (GPU), a field-programmable gate array (FPGA) to retrieve and execute instructions, other electronic circuitry suitable for the retrieval and execution instructions stored on a machine-readable storage medium, or a combination thereof.

As used herein, “rack unit” or “U” may refer to the unit of measurement to define the height of a rack frame and the height of the equipment in a rack frame (such as, computing devices). Each rack unit may be equivalent to 44.50 millimeters or 1.75 inches. For example, a computing device, such as a rack server, may have a height of 2 U or 2 rack units (in other words, 89 millimeters or 3.5 inches).

As used herein, “horizontal” and/or “horizontally” refer to directions that are parallel to a longitudinal dimension of the bracket assembly, whereas “vertical” and/or “vertically” refer to directions that are perpendicular to the horizontal. In FIGS. 1-6, “horizontal” directions are parallel to the y-axis, while “vertical” directions are parallel to the z-axis. Thus, both +y\hat{ } and −y\hat{ } may be “horizontal”, and both +z\hat{ } and −z\hat{ } directions may be “vertical”. When one of the example rail kits is installed in a rack, the “horizontal” directions may be parallel to a line extending between corresponding mounting holes in opposing columns of the device rack, and the “vertical” directions may be parallel to a direction in which the columns extend. Horizontal movement or extension is movement or extension in any horizontal direction, whereas vertical movement or extension is movement or extension in any vertical direction.

As used herein, “forward” refers to an orientation that is aligned with a horizontal vector pointing from a rear of the bracket assembly toward a front of the bracket assembly, while “rearward” refers to an orientation that is aligned with a horizontal vector pointing from a front of the bracket assembly toward a rear of the bracket assembly. In FIGS. 1-6, “forward” is aligned with the +y\hat{ } direction, while “rearward” is aligned with the −y\hat{ } direction. When one of the example rail kits is installed in a device rack, the “forward” orientation may be aligned with a vector extending from a rear column of the device rack to a front column of the device rack, and vice-versa for the “rearward” orientation. Forward movement or extension is movement or extension in a forward oriented direction, whereas rearward movement or extension is movement or extension in a rearward oriented direction.

As used herein, “inward” refers to an orientation that is aligned with a vector that would point from the rail kit toward the electronic device if the electronic device were mounted to the rail kit. As used herein and in the appended claims, “outward” refers to an orientation that is the opposite of the “inward” orientation (i.e., an orientation that is aligned with a vector that would point away from the electronic device if the electronic device were mounted to the rail kit). “Inward” and “outward” for one rail kit will not necessarily be identical to “inward” and “outward” for another rail kit, since the different rail kits may be oriented differently from one another. For example, when a pair of rail kits is installed in a device rack, they may be facing each other, and thus “inward” for one of the rail kits may be pointing in an opposite direction as “inward” for the other one of the rail kits. For example, in FIGS. 1-6, “inward” is aligned with the +x\hat{ } direction for the left-side rail kit 10L, and with the −x\hat{ } direction for the right-side rail kit 10R. Similarly, “outward” is aligned with the −x\hat{ } direction for the left-side rail kit 10L and the +x\hat{ } direction for the right-side rail kit 10R. Inward movement or extension is movement or extension in an inward oriented direction, whereas outward movement or extension is movement or extension in an outward oriented direction.

As used herein, a first element may be to “couple” with a second element if the first element is capable of extending into an opening defined by the second element.

As used herein, a first element may be considered to “prevent movement” of a second element in some specified direction if the first element constrains the second element such that it cannot move in the specified direction beyond some point; however, this does not imply that the first element necessarily has to keep the second element from any and all movement in the specified direction. In other words, when it is said that some element “locks” another element, this does not mean that it completely prevents all movement of the element, but rather that it sets some constraint on movement. For example, when it is said that the first latch prevents the inner slide and middle slide from moving in both the forward direction and the rearward direction when it is in the locked position, this means that the first latch constrains the movement of the inner slide in the forward and rearward directions to be within some finite range of positions; however, the first latch does not necessarily prevent the inner slide and outer slide from all forward and rearward motion and the inner slide and middle slide may move forward and rearward freely within the finite range. This reflects the fact that some finite tolerance or “wiggle room” may be inevitable due to manufacturing variances. In addition, in certain examples some finite tolerance or “wiggle room” may be intentionally included in the design to facilitate smooth functioning of the locking mechanism.

As used herein and in the appended claims, a first element is “connectable” to a second element if the first element is so configured that it is capable of being connected to the second element; however, this does not require that the first element actually be connected to the second element. For example, in the example rail kit the inner slide may not be connected to any electronic device initially, but the inner slide is nonetheless still “connectable” to an electronic device even in this state because the inner slide is so configured that it could be connected to an electronic device.

As used herein and in the appended claims, a first element is “engagable” by a second element if the first element is so configured that it is capable of being engaged by the second element; however, this does not require that the first element actually be engaged by the second element. For example, in the example rail kit the inner slide may not be engaged by the middle slide initially, but the inner slide is nonetheless still “engagable” by the middle slide even in this state because the inner slide is so configured that it could be engaged by the middle slide.

FIG. 1, as noted above, is a block diagram of a rail kit 100, according to an example. The rail kit 100 may include an outer slide 102. The outer slide 102 may include one or more guide pins at a front end and a back end to connect to apertures in a rack. The outer slide 102 may include protrusions or ears at both ends. The protrusions or ears may extend in an outward direction from the inside of the outer slide 102. Further the protrusions or ears may extend perpendicular from the ends of the outer slide 102. In such examples, the protrusions or ears may include the guide pins to connect to the rack. In another example, the outer slide 102 may include a channel or guide to accept or engage a middle slide 104. The outer slide 102 may vertically support the middle slide 104. Further, the outer slide 102 may allow the middle slide 104 to slide horizontally back and forth relative to the outer slide 102, without sliding past the back end of the outer slide 102. In another example, the outer slide 102 may include an aperture. In an example, the aperture may correspond to a first latch 106 of the middle slide 104 when the middle slide 104 is in a first position or a partially extended position.

In another example, the rail kit 100 may include a middle slide 104. As noted, the middle slide 104 may be retained, supported, and/or engaged by the outer slide 102. In another example, the middle slide 104 may include a channel or guide to accept or engage an inner slide 108. The middle slide 104 may vertically support the inner slide 108. Further, the middle slide 104 may allow the inner slide 108 to slide horizontally back and forth relative to the middle slide 104, without sliding past the back end of the middle slide 104.

In another example, the middle slide 104 may include a first latch 106 (also referred to as a lock latch, middle slide latch, etc.). In a further example, the middle slide 104 may include the first latch 106 closer towards the back end of the middle slide 104. In another example, the first latch 106 may comprise an end fixedly attached or staked to the middle slide 104. The first latch 106 may include a protrusion extending out from the middle slide 104 (out, as in, out in the direction of the inner side of the middle slide 104). As an inner slide 108 is positioned in the middle slide 104, the inner slide 108 may press against the first latch 106 (particularly, the protrusion extending out from the first latch 106 of the middle slide 104). The force exerted by the inner slide 108 on the first latch 106 may push an end portion of the first latch 106 towards the outer side of the middle slide 104, such that as the inner slide 108 and middle slide 104 are pulled out, when the first latch 106 corresponds with the aperture of the outer slide 102, then the first latch 106 may be pushed into the aperture of the outer slide 102. This action may lock the middle slide 104 and inner slide 108 into place, preventing the middle slide 104 and inner slide 108 from moving in any direction. In other words, the middle slide 104 and inner slide 108 may lock into place. In another example, the middle slide 104 may include a cable arm management connector located at the back end of the middle slide 104.

As noted above, the rail kit 100 may include an inner slide 108. The inner slide 108 may support, engage, and/or retain the middle slide 104. The inner slide 108 may be supported by the middle slide 104. The inner slide may slide horizontally in relation to the middle slide 104. In another example, the inner slide 108 may include a cable arm management connector. In a further example, the cable arm management connector may be located at the back of inner slide 108. In another example, the inner slide 108 may attach directly to a computing device. In such examples, a user may connect the inner slide 108 to the side of a computing device and connect another inner slide 108 to the other side of the computing device (each side of the computing device being parallel). Once the inner slides 108 are attached to the computing device, the user may attach or insert the inner slides 108 to corresponding middle slides 104. In such examples, the middle slides 104 may be attached to or inserted in outer slides 102 and the outer slides 102 may be attached to a rack.

In another example, the inner slide 108 may include a second latch 110. The second latch 110 may actuate the first latch 106. The actuation may occur when the second latch 110 is depressed or pressed. For example, a user may press and hold the second latch 110 while pulling (thus, pulling the inner slide 108). Further, as the user pulls (while continuing to press or depress the second latch 110), the first latch 108 may be actuated, thus allowing the middle slide 104 and inner slide 108 to move. The second latch 110 may be located near the end of the inner slide 108. Further, the second latch 110 may be located on the backside of the inner slide 108. In another example, the first latch 106 may be actuated by an amount of force over a limit. For example, the first latch may be constructed in such a way that, when the middle slide 104 and inner slide 108 are in a first position, the middle slide 104 and inner slide may be moved if a certain amount of force exerted, rather than a second latch 110 actuating the first latch 106. For example, a user may hold an end of the inner slide 108 and pull harder than normal. The force exerted by the user may be enough to allow actuation of the first latch 106, thus allowing the middle slide 104 and inner slide 108 to move. In another example, the second latch 110 may be located at or disposed on the middle slide 104 or outer slide 102. In such examples, the second latch may be a button, latch, switch, or some other means to actuate the first latch 106.

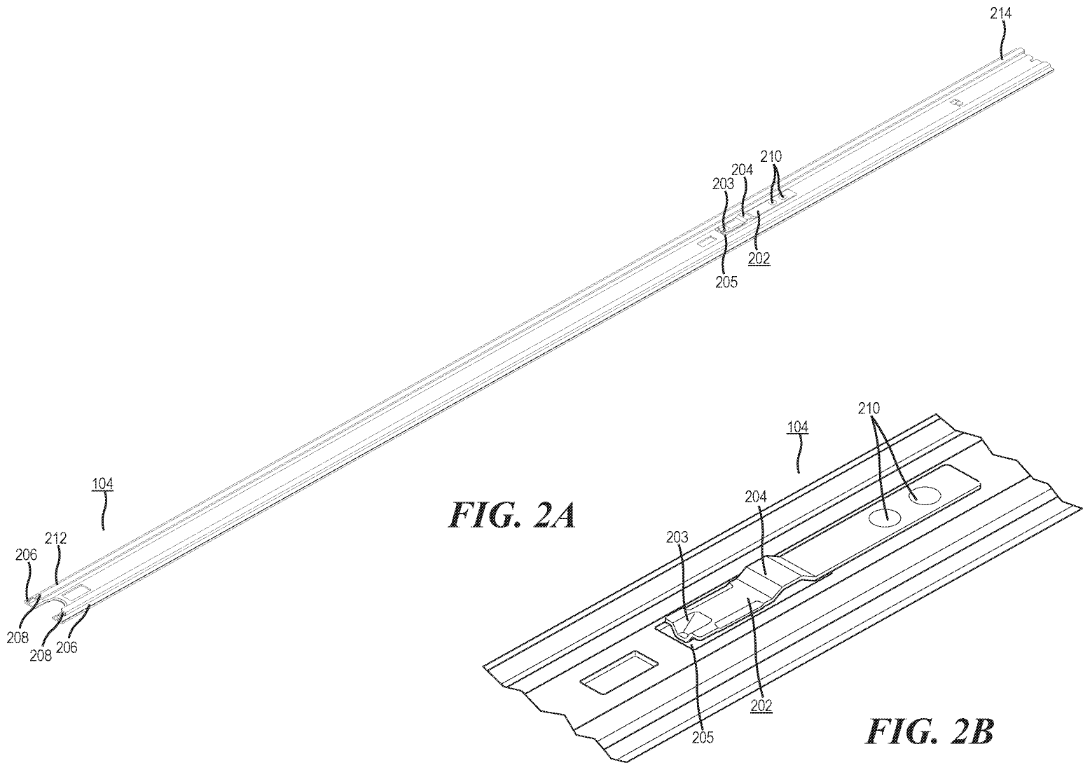

FIGS. 2A and 2B are schematic views of a middle slide 104, according to an example. In such examples and as noted above, the rail kit 100 may include a middle slide 104. The middle slide 104 may include a front end 212 and a back end 214. When inserted into or attached to an outer slide, the middle slide 104 may be slid, back end 214 first, into the outer slide. The middle slide 104 may include a first set of channels 208 to allow for insertion or attachment of an inner slide. The middle slide 104 may include a second set of guides 206 to allow the middle slide 104 to be inserted into or attached to an outer slide.

In another example, the middle slide 104 may include a lock latch 202 (also referred to as a latch, the first latch, or middle slide latch). The lock latch 202 may be disposed at some point on the middle slide 104. In a further example, the point of the location of the lock latch 202 may be closer to the back end 214 of the middle slide 104. In another example, the location of the lock latch 202 may correspond to the location of an aperture of the outer slide when the middle slide 104 is in first position or partially extended position.

In another example, the lock latch 202 may include a fixed portion 210. The fixed portion 210 may be fixedly attached or staked to the middle slide 104. In another example, the lock latch may include a raised portion 204 or protrusion and/or a flexible portion 203. When no force is exerted on the raised portion 204, the flexible portion 203 may not be pushed or forced into aperture 205. In an example, when an inner slide is positioned over the lock latch 202, the raised portion 204 is forced or pushed down. The force exerted against the raised portion 204 may cause the flexible portion 203 to flex downwards or backwards through aperture 205. In such cases, and in particular when the middle slide 104 is inserted or attached to an outer slide, the flexible portion 203 may extend into an aperture of the outer slide, thus locking the middle slide 104 and an inner slide in place.

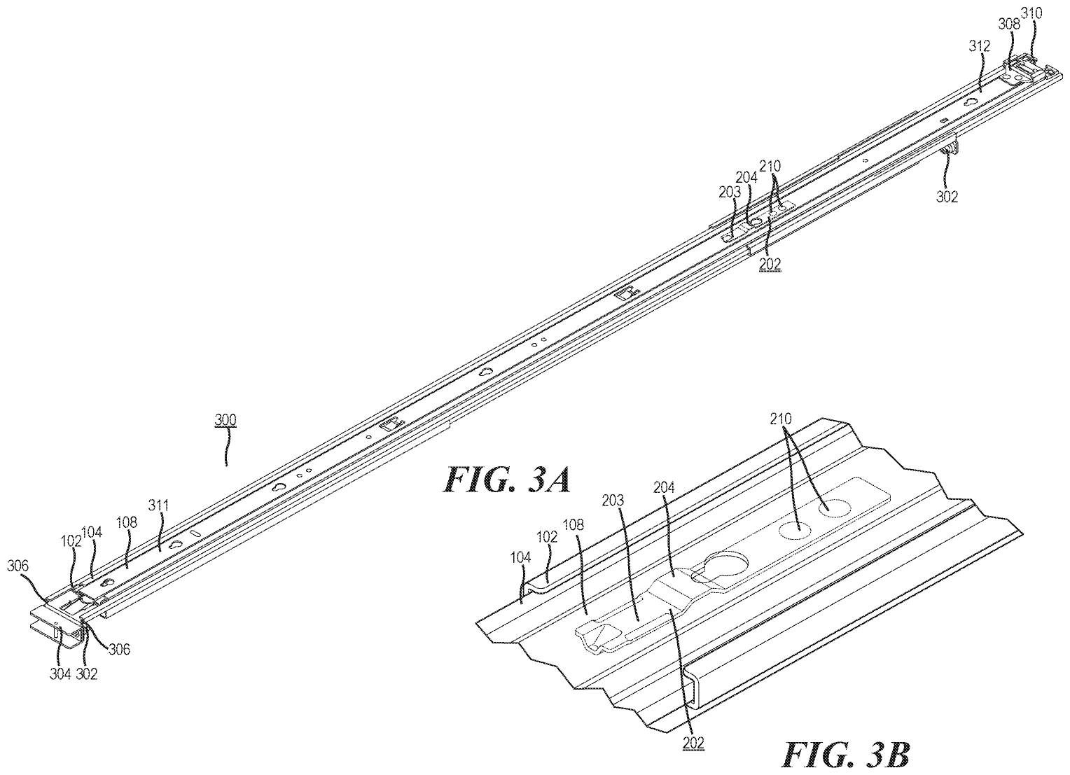

FIGS. 3A and 3B are schematic views of a rail kit 300 in a retracted position, according to an example. In an example, the rail kit 300 may be in a retracted position or, in other words, the middles slide 104 and inner slide 108 may be pushed in as far as allowed or fully inserted into the outer slide 102. In another example, inner slide 108 may be attached to a computing device. In a further example, the computing device may be a rack server. In another example, rail kit 300 may be installed in a rack. In another example, when a user would like to view, swap, remove, or add a component to a computing device, the user may pull the inner slide 108 or pull the computing device housing the component to a first position or a partially extended or extracted position. As the user pulls the inner slide 108 or computing device, the inner slide 108 and middle slide 104 may move forward (in the direction pulled). At a point where a first set of components or device of a computing device are accessible, the inner slide 108 and middle slide 104 may stop. In particular, lock latch 202 may prevent further movement of the inner slide 108 and middle slide 104, at least until lock latch 202 is actuated. In another example, the retracted position may be the position that a user pushes the inner slide 108 and middle slide 104 to from a first position or partially extended or extracted position.

In another example and as noted above, the rail kit 100 may include an inner slide 108. The inner slide 108 may include a front end 311 and a back end 312. When inserted into or attached to a middle slide 104, the inner slide 108 may be slid, back end 312 first, into the middle slide 104. The inner slide 108 may include a set of guides to allow the inner slide 108 to be inserted into or attached to a middle slide 104.

In another example, the inner slide 108 may cover the lock latch 202 included on the middle slide 104. In such examples, the inner slide 108 may push or force down the lock latch 202 located on the middle slide 104. As indicated by the dotted line illustration in FIGS. 3A and 3B, the lock latch 202 may not be viewed in the retracted position, as the lock latch 202 may be covered by the inner slide 108.

In another example, the outer slide 102 may include channels 306 to accept, retain, and/or support middle slide 104. In another example, the outer slide 102 may include protrusions 304 or ears. The protrusions may be disposed perpendicular on the outer slide 102 at both ends. In a further example, the protrusions may include guide pins 302. Guide pins 302 may connect to apertures included on a rack. In another example, the middles slide 104 and/or inner slide 108 may include cable arm management connectors 310 and 308, respectively.

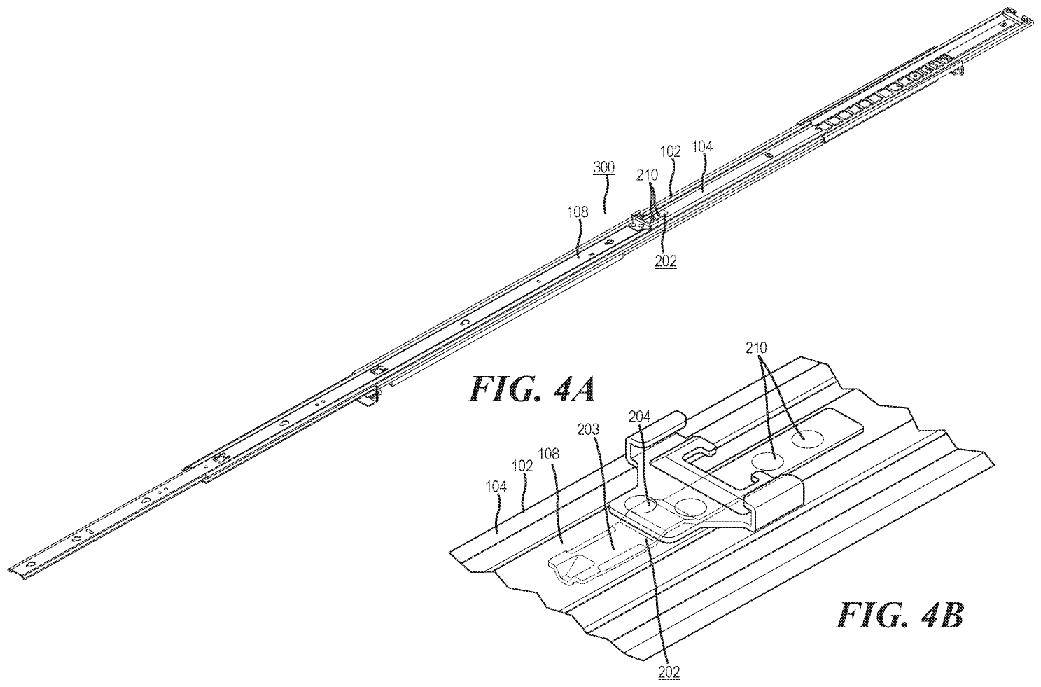

FIGS. 4A and 4B are schematic views of a rail kit 300 in a partially extended position, according to an example. In an example, rail kit 300 may be extended or extracted from a retracted position to a partially extended position or a first position. In another example, rail kit 300 may be pushed or retracted from a fully extended position to a partially extended position. In another example, a user may access various components or devices in a computing device in partially extended position. For example, a user may access storage components of a computing device or rack server, when the computing device or rack server is in the partially extended position.

In another example, as the inner slide 108 is pulled from a retracted position of the rail kit 300 or pushed from a fully extended or extracted position, when the lock latch 202 reaches a certain point, the lock latch 202 may lock the rail kit 300 in place. In other words, the lock latch 202 may lock the inner slide 108 and middle slide 104 into the partially extended position (i.e., the inner slide 108 and middle slide 104 may not be able to move). In another example, in the partially extended position, a portion of the lock latch 202 may be exposed. When the rail kit 300 is attached to a computing device, the lock latch 202 may not be visible, as the computing device may block a view of the inner side of the rail kit 300.

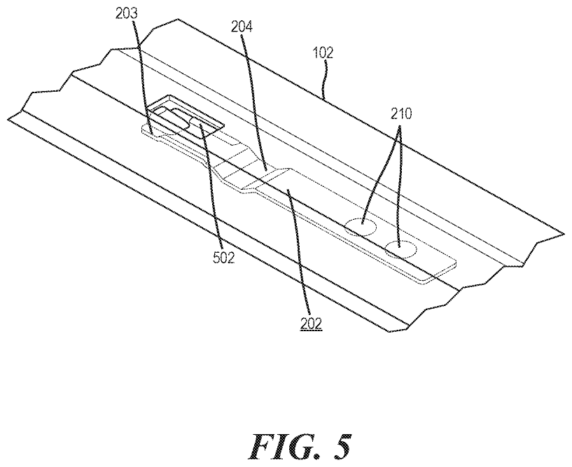

FIG. 5 is a schematic view of the opposite side of a section of an outer slide 102 and a lock latch 202, according to an example. In such examples, the middle slide and inner slide may be in a partially extended position. Further, when the middle slide and inner slide are in a partially extended position, the latch or lock latch 202 may be forced into or pushed into (for example, by the force of the inner slide pushing against protrusion 204) an aperture 502. In a further example, the flexible portion 203 of the lock latch 202 may be forced into aperture 502. Further, an edge of the aperture 502 may align with the end of the flexible portion 203 of the lock latch 202. In other words, the end of the flexible portion 203 may push against the edge of the aperture 502, thus preventing movement of the middle slide and inner slide. In another example, the outer slide 102 may include a depression, rather than an aperture 502, for the lock latch 202 to catch or to force the flexible member 203 into. In another example, the outer slide 102 may include a catch or some other means of stopping movement of a middle slide and inner slide, based on interaction with the lock latch 202.

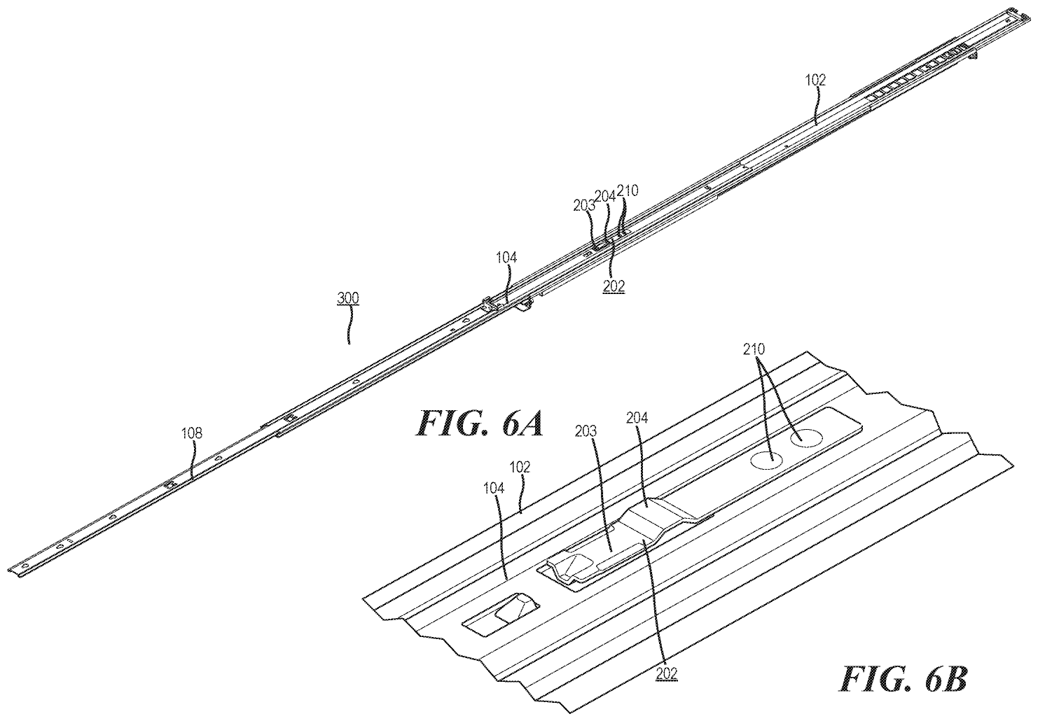

FIGS. 6A and 6B are schematic views of a rail kit 300 in an extended position or second position, according to an example. In an example, the inner slide 108 and middle slide 104 may be extended fully (as in, a fully extended position). In such examples, when the inner slide 108 and middle slide 104 are fully extended, a user may access more or all of the components or devices of a computing device attached to the rail kits 300. In another example, a user may remove the computing device from a rack when the rail kit 300 is in a fully extended position. In an example, when the rail kit 300 is in a partially extended position, a user may actuate the lock latch 202 and pull the inner slide 108 (or pull the computing device attached to the inner slide 108) into the fully extended position. The actuation of the lock latch 202 may allow the inner slide 108 and middle slide 104 to move in a back and forth direction, thus allowing the rail kit 300 to move from a partially extended position to a fully extended position (or to a retracted position).

In another example, a user may attach an inner slide 108 of rail kit 300 to a side of a computing device. The user may then attach another inner slide 108 of another rail kit 300 to the other side of the computing device (the side being parallel to the other side). A user may then drop in the computing device to the rest of the rail kit. In other words, the user may attach the computing device plus the inner slides 108 to the middle slide 104 (as in the inner slide 108 would engage the middle slide 104). Once the user has added the computing device, the user may push the computing device to a partially extended position. The rail kit 300 may lock into place at the partially extended position. In such examples, to move the computing device further in the rack, a user may need to actuate a middle slide latch or lock latch 202 disposed on the middle slide 104. When the user actuates the lock latch 202, the user may be able to push the computing device fully into the rack (in other words, a retracted position).

The present disclosure has been described using non-limiting detailed descriptions of examples thereof and is not intended to limit the scope of the present disclosure. It should be understood that features and/or operations described with respect to one example may be used with other examples and that not all examples of the present disclosure have all of the features and/or operations illustrated in a particular figure or described with respect to one of the examples. Variations of examples described will occur to persons of the art. Furthermore, the terms “comprise,” “include,” “have” and their conjugates, shall mean, when used in the present disclosure and/or claims, “including but not necessarily limited to.”

It is noted that some of the above described examples may include structure, acts or details of structures and acts that may not be essential to the present disclosure and are intended to be examples. Structure and acts described herein are replaceable by equivalents, which perform the same function, even if the structure or acts are different, as known in the art. Therefore, the scope of the present disclosure is limited only by the elements and limitations as used in the claims

What is claimed is:

1. A rail kit, comprising:
an outer slide;
a middle slide retained by a side of the outer slide, wherein the middle slide is horizontally slidable, relative to the outer slide, to a first position and a second position and wherein the middle slide includes a first latch to stop the middle slide from extending to the second position when the middle slide is extended from a fully inserted position to the first position; and
an inner slide retained by the middle slide, wherein the inner slide is horizontally slidable, relative to the middle slide, to the first position and the second position and wherein the inner slide includes a second latch, wherein when the second latch is depressed and when the inner slide and middle slide are in the first position, the first latch is actuated and the inner slide and middle slide are extended to the second position.

2. The rail kit of claim 1 wherein, the inner slide connects to a side of a computing device.

3. The rail kit of claim 1, wherein the outer slide includes an aperture.

4. The rail kit of claim 3, wherein, when the middle slide and inner slide are in the first position, the first latch extends through the aperture included on the outer slide to prevent the middle slide and inner slide from extending to the second position.

5. The rail kit of claim 1, wherein the second latch is positioned at a front end of the inner slide.

6. The rail kit of claim 1, wherein, when the inner slide and the middle slide are not in the first position and second position, the inner slide and middle slide are fully retracted in the outer slide.

7. A system, comprising:
a computing device;
a rack; and
a first rail kit of claim 1, wherein the inner slide of the first rail kit is attached to a first side of the computing device, and a second rail kit of claim 1, wherein the inner slide of the second rail kit is attached to a second side of the computing device,
wherein the first side of the computing device and the second side of the computing device are parallel;
wherein the computing device is attached to the rack via the first rail kit and the second rail kit.

8. A rail kit, comprising:
an inner slide including a release latch;
a middle slide to engage the inner slide, wherein the middle slide includes a lock latch and wherein the inner slide is vertically supported and horizontally slideable relative to the middle slide; and
an outer slide to engage the middle slide, wherein the middle slide is vertically supported and horizontally slideable relative to the outer slide,
wherein, in a retracted position, the inner slide is retracted into the middle slide and the middle slide is retracted into the outer slide,
wherein, in a partially extended position, the inner slide is partially extended out of the middle slide and the middle slide is partially extended from the outer slide, and
wherein, in an extended position, the inner slide is extended out, to a maximum distance, of the middle slide and the middle slide is extended out, to a maximum distance, of the outer slide.

9. The rail kit of claim 8, wherein, when the inner slide and middle slide are moved to the partially extended position, the lock latch locks the inner slide and middle slide form extending further.

10. The rail kit of claim 8, wherein the outer slide includes an aperture.

11. The rail kit of claim 10, wherein the inner slide applies force to the lock latch.

12. The rail kit of claim 11, wherein the force applied to the lock latch pushes the lock latch in the aperture of the outer slide as the lock latch moves to the aperture.

13. The rail kit of claim 10, wherein, when the inner slide and middle slide are moved to the partially extended position, the lock latch extends into the aperture to lock the inner slide and middle slide from extending or retracting further.

14. The rail kit of claim 13, wherein the release latch of the inner slide is actuated to actuate the lock latch.

15. The rail kit of claim 14, wherein the release latch is actuated to allow movement of the inner slide and middle slide to the extended position or the retracted position

16. The rail kit of claim 14, wherein the release latch of the inner slide is a button.

17. The rail kit of claim 8, wherein the inner slide attaches directly to a computing device.

18. The rail kit of claim 8, wherein both ends of the outer slide include guide pins to connect to a rack.

19. A system, comprising:
a computing device;
a rack; and
a first rail kit of claim 8, wherein the inner slide of the first rail kit is attached to a first side of the computing device, and a second rail kit of claim 8, wherein the inner slide of the second rail kit is attached to a second side of the computing device,
wherein the first side of the computing device and the second side of the computing device are parallel;
wherein the computing device is attached to the rack via the first rail kit and the second rail kit.

20. The system of claim 19, wherein the computing device is extendable from the rack via the first and second rail kit to the partially extended position and the extended position.
